(19) United States
(12) Patent Application Publication
(10) Pub. No.: US 2013/0193571 A1
(43) Pub. Date: Aug. 1, 2013

(54) SEMICONDUCTOR PACKAGE AND METHOD AND SYSTEM FOR FABRICATING THE SAME

(71) Applicant: XINTEC INC., Jhongli City (TW)

(72) Inventor: Yu-Lung Huang, Jhongli City (TW)

(73) Assignee: XINTEC INC., Jhongli City (TW)

(21) Appl. No.: 13/743,524

(22) Filed: Jan. 17, 2013

Related U.S. Application Data
(60) Provisional application No. 61/587,829, filed on Jan. 18, 2012.

(51) Int. Cl. H01L 21/56; H01L 23/498

(52) U.S. Cl. CPC H01L 21/56; H01L 23/49811
USPC 257/737; 438/109; 29/738

(57) ABSTRACT

A fabrication method of a semiconductor package includes: disposing a first wafer on a substrate having at least a conductive pad; stacking a second wafer on the first wafer, wherein the second wafer has a pre-open area corresponding in position to the conductive pad of the substrate; forming a protection layer on the second wafer; embrittling the protection layer on the pre-open area of the second wafer; and removing the embrittled portion of the protection layer and portions of the second and first wafers so as to form an opening to expose the conductive pad, thereby preventing an adhesive layer from being attached to a cutting tool as in the prior art.

### BACKGROUND OF THE INVENTION

1. Field of the Invention

The present invention relates to semiconductor packages, and more particularly, to a semiconductor package having stacked structure and a method and system for fabricating the same.

2. Description of Related Art

Along with the rapid development of electronic industries, electronic products are required to have multiple functions. Accordingly, semiconductor packages and electronic elements having various functions are generally disposed on a circuit board of an electronic product. However, along with the increase of the number of the semiconductor packages and electronic elements, the circuit board is required to have more space for accommodating the semiconductor packages and electronic elements and hence the size of the electronic product must be increased. Therefore, to meet the miniaturization requirement of electronic products, semiconductor packages are usually integrated with electronic elements so as to form MEMS (Micro Electro Mechanical System) packages, thereby saving space on circuit boards, reducing the size of the electronic products and meeting the multi-function requirement.

FIGS. 1A and 1B show a conventional fabrication method of a semiconductor package 1. Referring to FIG. 1A, a first wafer 11 is disposed on a substrate 10 having a conductive pad 100. A second wafer 12 is bonded to the first wafer 11 and a cavity 12a is formed in the second wafer 12. Then, an adhesive layer 13 is formed on the second wafer 12 to cover the cavity 12a. Referring to FIG. 1B, a cutting process is performed along a line L of FIG. 1A to remove portions of the adhesive layer 12 and the second wafer 12, thereby exposing the conductive pad 100. Subsequently, the adhesive layer 13 is cured so as to be removed and then an electronic element (not shown) is received in the cavity 12a. The conductive pad 100 can be electrically connected to other electronic devices (not shown) through wire bonding.

However, in the above-described cutting process, the adhesive property of the adhesive layer 13 causes the adhesive material to be easily attached to the cutting tool, thereby resulting in a high resistant force during the cutting process and hence adversely affecting the cutting process. Further, some pieces of the adhesive material may remain on the cutting tool after the cutting process. As such, the cutting tool cannot be easily cleaned and can be easily damaged by the remaining pieces of the adhesive material.

Furthermore, during the cutting process, some pieces 13a of the adhesive layer 13 may fall on the conductive pad 100. The pieces of the adhesive layer cannot be easily removed due to their adhesive property, thus adversely affecting the electrical performance of the conductive pad 100.

Therefore, there is a need to provide a semiconductor package and a method and system for fabricating the semiconductor package so as to overcome the above-described drawbacks.

### SUMMARY OF THE INVENTION

In view of the above-described drawbacks, the present invention provides a fabrication method of a semiconductor package, which comprises the steps of: disposing a first wafer on a substrate having at least a conductive pad; stacking a second wafer on the first wafer, wherein the second wafer has a pre-open area corresponding in position to the at least a conductive pad of the substrate; forming a protection layer on the second wafer; embrittling a portion of the protection layer positioned on the pre-open area of the second wafer; and removing the embrittled portion of the protection layer and portions of the second and first wafers so as to form an opening to expose the at least a conductive pad. Since the embrittled portion of the protection layer is not adhesive, it results in a reduced resistant force during the cutting process and no adhesive material is left on the cutting tool after the cutting process.

Further, during the cutting process, some pieces of the embrittled portion may fall on the conductive pad. Since the embrittled portion is not adhesive, the pieces of the embrittled portion on the conductive pad can be easily removed.

The present invention further provides a system for fabricating a semiconductor package, which comprises: a carrying device for carrying a semiconductor package, wherein the semiconductor package has a substrate having at least a conductive pad and a first wafer and a second wafer sequentially disposed on the substrate, and the second wafer has a pre-open area corresponding in position to the conductive pad; a molding device for forming a protection layer on the second wafer; an embrittling device for embrittling a portion of the protection layer positioned on the pre-open area of the second wafer; and a cutting device for cutting the first and second wafers along the pre-open area to remove the embrittled portion of the protection layer and portions of the second and first wafers, thereby forming an opening for exposing the at least a conductive pad

The present invention further provides a semiconductor package, which comprises: a substrate having a die attach area and at least a conductive pad disposed at an outer periphery of the die attach area; a first chip disposed on the die attach area of the substrate; a second chip disposed on the first chip and having a side surface corresponding in position to the die attach area so as to expose the at least a conductive pad of the substrate; a first protection layer formed on a portion of the second chip and extending to an upper edge of the side surface of the second chip; and a second protection layer formed on a portion of the second chip and connecting the first protection layer, wherein the first protection layer is greater in brittleness than the second protection layer.

### BRIEF DESCRIPTION OF DRAWINGS

FIGS. 1A and 1B are schematic cross-sectional views showing a conventional method for fabricating a semiconductor package;

FIGS. 2A to 2D are schematic cross-sectional views showing a method for fabricating a semiconductor package according to the present invention; and

FIG. 3 is a block diagram showing a system for fabricating a semiconductor package according to the present invention.

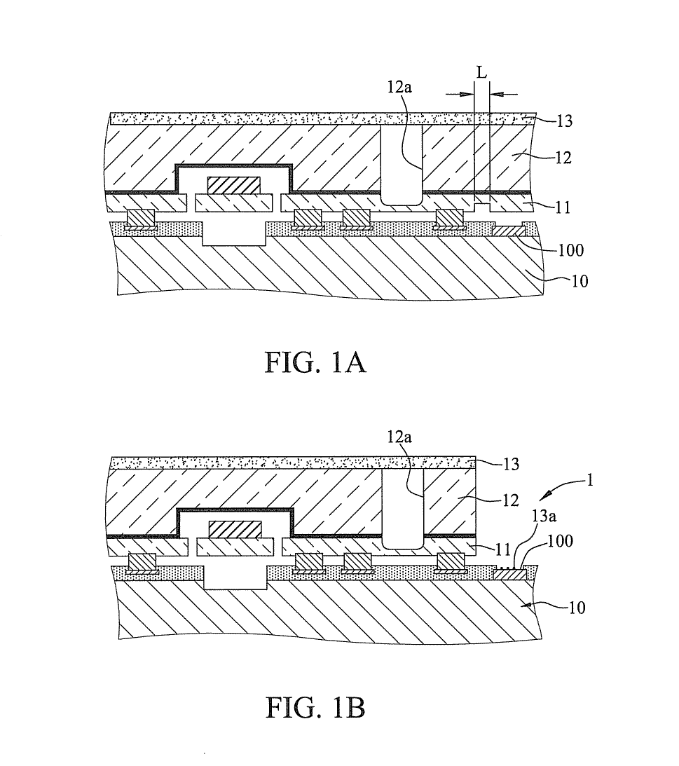

### DETAILED DESCRIPTION OF PREFERRED EMBODIMENTS

The following illustrative embodiments are provided to illustrate the disclosure of the present invention, these and other advantages and effects can be apparent to those in the art after reading this specification.

It should be noted that all the drawings are not intended to limit the present invention. Various modification and variations can be made without departing from the spirit of the present invention. Further, terms such as “one”, “on”, “upper” etc. are merely for illustrative purpose and should not be construed to limit the scope of the present invention.

The present invention provides a semiconductor package applicable to various kinds of micro-electro-mechanical systems (MEMS), especially image sensors that provide measurements based on electrical or capacitive changes. Particularly, wafer level package (WSP) processes can be applied to semiconductor packages of image sensor elements, RF circuits, accelerators, gyroscopes, micro actuators or pressure sensors.

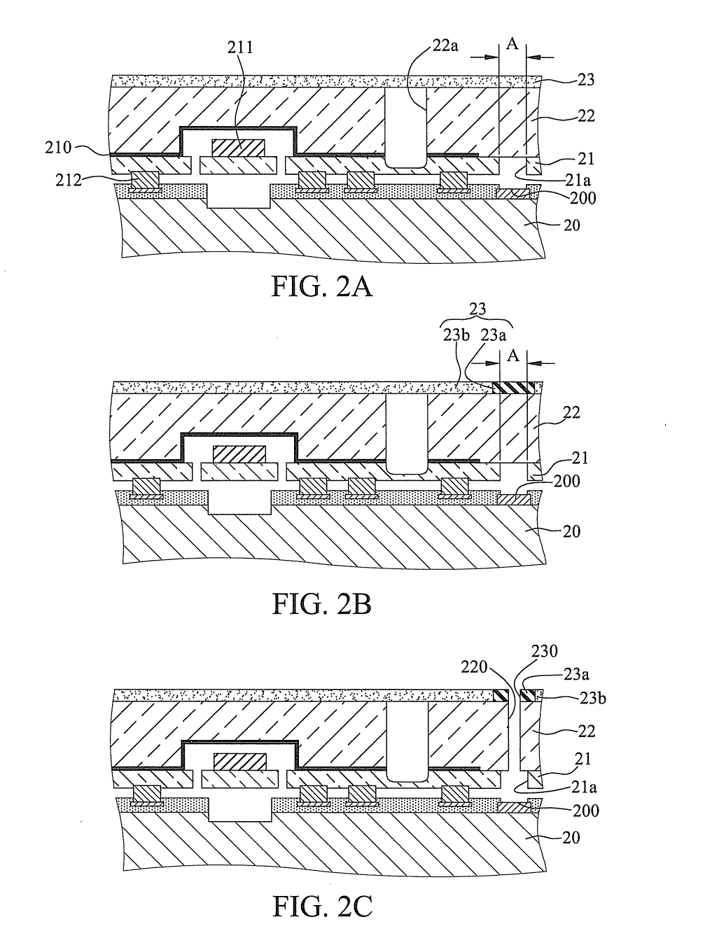

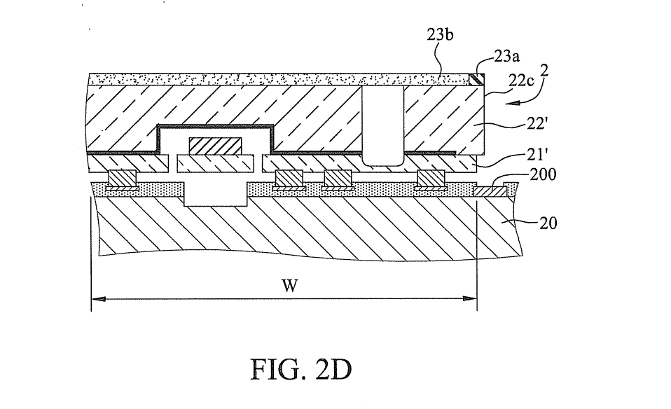

FIGS. 2A to 2D are schematic cross-sectional views showing a fabrication method of a semiconductor package 2 according to the present invention.

Referring to FIG. 2A, a substrate 20 having a plurality of conductive pads 200 on a surface thereof is provided. A first wafer 21 is disposed on the substrate 20 through a plurality of bumps 212, and an etch stop layer 210 is formed on the first wafer 21 so as for a second wafer 22 to be bonded thereto. The second wafer 22 has a pre-open area A corresponding in position to the conductive pads 200 of the substrate 20. A cavity 22a is further formed in the second wafer 22 through etching for exposing a portion of the first wafer 21.

Then, a protection layer 23 is formed on the second wafer 22 so as to cover the cavity 22a.

In the present embodiment, the substrate 20 has a CMOS (Complementary Metal-Oxide-Semiconductor) wafer structure. In other embodiments, the substrate 20 can be a ceramic circuit board, a metal plate and so on. The first wafer 21 is electrically connected to the substrate 20. An electronic element such as a gyroscope 211 is disposed on the first wafer 21 so as for the first wafer 21 to have a MEMS. The second wafer 22 serves as a covering member. The protection layer 23 can be made of a photosensitive adhesive material, such as a UV tape.

The substrate 20, the first wafer 21 and the second wafer 22 form a stack wafer group. Internal circuits of each of the wafers can be designed according to the practical requirement. Since the internal circuits are not characteristics of the present invention, detailed description thereof is omitted herein. Further, a first opening 21a can be selectively formed in the first wafer 21 at a position corresponding to the conductive pad 200.

Referring to FIG. 2B, by patterning a photoresist layer, light such as UV light is radiated on the protection layer 23 on the pre-open area A and around the periphery of the pre-open area A so as to embrittle the photosensitive adhesive material of the protection layer 23, i.e., cure the photosensitive adhesive material of the protection layer 23. Consequently, the embrittled portion of the protection layer 23 serves as a first protection layer 23a and the other portion of the protection layer 23 serves as a second protection layer 23b.

Referring to FIG. 2C, the first protection layer 23a on the pre-open area A and the second wafer 22 in the pre-open area A are cut and removed by a cutting tool (not shown) so as to form a second opening 220 and a third opening 230 in communication with the first opening 21a, thereby exposing the conductive pad 200.

The present embodiment dispenses with cutting the first wafer 21 due to the formation of the first opening 21a.

Referring to FIG. 2D, a singulation process is performed. Subsequently, the second protection layer 23b can be cured and then the first and second protection layers 23a, 23b can be removed so as for an electronic element (not shown) to be received in the cavity 22a. The conductive pad 200 can further be electrically connected to other electronic devices (for example, a circuit board) through wire bonding.

The present invention embrittles the protection layer 23 on the pre-open area A so as to cause the protection layer 23a to lose its adhesive property, thereby leading to a reduced resistant force during the cutting process. In addition, no adhesive material is left on the cutting tool after the cutting process.

During the cutting process, some pieces of the first protection layer 23a may fall on the conductive pad 200. Since the first protection layer 23a is not adhesive, the pieces of the first protection layer 23a on the conductive pad 200 can be easily removed so as to ensure the electrical performance of the conductive pad 200.

Further, if the first protection layer 23a on the pre-open area A is removed through laser cutting, no adhesive material falls on the conductive pad 200, thereby dispensing with the cleaning process of the conductive pads 200.

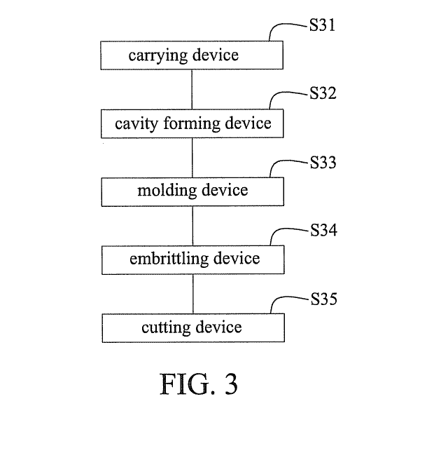

FIG. 3 provides a system for fabricating a semiconductor package according to the present invention. The system has: a carrying device S31 for carrying a semiconductor package 2, a cavity forming device S32 for forming a cavity 22a, a molding device S33 for forming a protection layer 23, an embrittling device S34 for embrittling the protection layer 23, and a cutting device S35. Therein, the semiconductor package 2 has a substrate 20 having a plurality of conductive pads 200 and a first wafer 21 and a second wafer 22 sequentially disposed on the substrate 20. The second wafer has a pre-open area A corresponding in position to the conductive pad 200.

The cavity forming device S32 is used for forming the cavity 22a in the second wafer 22.

The molding device S33 is used for forming the protection layer 23 on the second wafer 22 so as to cover the cavity 22a.

The embrittling device S34 has a light source (not shown) that radiates light on the protection layer 23 on the pre-open area A for embrittling a portion of the protection layer 23 positioned on the pre-open area A.

The cutting device S35 can be a knife type tool (not shown) or a laser type tool (not shown), which is used to cut along the pre-open area A to remove the embrittled first protection layer 23a, portions of the second and first wafers 22, 21, thereby forming an opening for exposing the conductive pad 200. Then, a singulation process can be performed.

The present invention further provides a semiconductor package 2, which has: a substrate 20, a first chip 21 disposed on the substrate 20, a second chip 22 disposed on the first chip 21, and a first protection layer 23a and a second protection layer 23b disposed on portions of the second chip 22, respectively. The substrate 20 has a CMOS chip structure, which has a die attach area W and a plurality of conductive pads 200 at an outer periphery of the die attach area W.

The first chip 21 is disposed on the die attach area W through a plurality of bumps 212 and has a gyroscope 211.

The second chip 22 has a side surface 22c corresponding in position to the die attach area W so as to expose the conductive pad 200. The second chip 22 has a cavity 22a for exposing a portion of the first chip 21.

The first protection layer 23a is formed on a portion of the second chip 22 and extends to an upper edge of the side surface 22c of the second chip 22. The first protection layer 23a is made of a brittle material.

The second protection layer 23b is formed on a portion of the second chip 22 and connects the first protection layer 23a. The second protection layer 23b is made of an adhesive material such that the first protection layer 23a is more brittle than the second protection layer 23b.

Therefore, the present invention embrittles the adhesive material on a pre-open area so as to cause the adhesive material on the pre-open area to lose its adhesive property, thereby facilitating the cutting process and preventing damages of the cutting tool.

The above-described descriptions of the detailed embodiments are only to illustrate the preferred implementation according to the present invention, and it is not to limit the scope of the present invention. Accordingly, all modifications and variations completed by those with ordinary skill in the art should fall within the scope of present invention defined by the appended claims.

What is claimed is:

1. A semiconductor package, comprising:
a substrate having a die attach area and at least a conductive pad disposed at an outer periphery of the die attach area;
a first chip disposed on the die attach area of the substrate;
a second chip disposed on the first chip and having a side surface corresponding in position to the die attach area so as to expose the conductive pad of the substrate;
a first protection layer formed on a portion of the second chip and extending to an upper edge of the side surface of the second chip; and
a second protection layer formed on a portion of the second chip and connecting the first protection layer, wherein the first protection layer is greater in brittleness than the second protection layer.

2. The package of claim 1, wherein the substrate has a chip structure.

3. The package of claim 1, wherein the first chip or the second chip has a MEMS (Micro Electro Mechanical System).

4. The package of claim 1, wherein the first chip is disposed on the substrate through a plurality of bumps.

5. The package of claim 1, wherein the second chip has a cavity for exposing a portion of the first chip.

6. The package of claim 5, wherein the second protection layer covers the cavity.

7. The package of claim 1, wherein the first protection layer is made of a brittle material.

8. The package of claim 1, wherein the second protection layer is made of an adhesive material.

9. A fabrication method of a semiconductor package, comprising the steps of:
disposing a first wafer on a substrate having at least a conductive pad;
stacking a second wafer on the first wafer, wherein the second wafer has a pre-open area corresponding in position to the at least a conductive pad of the substrate;
forming a protection layer on the second wafer;
embrittling a portion of the protection layer positioned on the pre-open area of the second wafer; and
removing the embrittled portion of the protection layer and portions of the second and first wafers so as to form an opening to expose at least a the conductive pad.

10. The method of claim 9, wherein the substrate has a wafer structure.

11. The method of claim 9, wherein the protection layer is made of a photosensitive material.

12. The method of claim 11, wherein the embrittling process comprises radiating light on the protection layer on the pre-open area for embrittling the photosensitive material of the protection layer.

13. The method of claim 9, wherein the embrittled portion of the protection layer and a portion of the second wafer in the pre-open area are removed by cutting.

14. The method of claim 9, further comprising etching the second wafer to form a cavity and forming the protection layer to cover the cavity.

15. A system for fabricating a semiconductor package, comprising:
a carrying device for carrying a semiconductor package, wherein the semiconductor package has a substrate having at least a conductive pad and a first wafer and a second wafer sequentially disposed on the substrate, and the second wafer has a pre-open area corresponding in position to the at least a conductive pad;
a molding device for forming a protection layer on the second wafer;
an embrittling device for embrittling a portion of the protection layer positioned on the pre-open area of the second wafer; and
a cutting device for cutting the first and second wafers along the pre-open area to remove the embrittled portion of the protection layer and portions of the second and first wafers, thereby forming an opening for exposing the at least a conductive pad.

16. The system of claim 15, wherein the embrittling device has a light source that radiates light onto the protection layer on the pre-open area.

17. The system of claim 15, wherein the cutting device is a laser or knife type cutting device.

18. The system of claim 15, further comprising a cavity forming device for forming a cavity in the second wafer, wherein the cavity is further covered by the protection layer formed by the molding device.
